(19) United States
(12) Patent Application Publication
(10) Pub. No.: US 2017/0309552 A1
(43) Pub. Date: Oct. 26, 2017

(54) SYSTEM AND METHOD FOR VERIFYING USERS FOR A NETWORK SERVICE USING EXISTING USERS

(71) Applicant: Uber Technologies, Inc., San Francisco, CA (US)

(72) Inventors: Sean Zachary Singleton, San Francisco, CA (US); Michael O'Herlihy, San Francisco, CA (US); Meron Alon, San Francisco, CA (US); Matthew Joseph Doyle, San Francisco, CA (US); Katherine Rose McDonald, San Francisco, CA (US)

(21) Appl. No.: 15/640,155

(22) Filed: Jun. 30, 2017

Related U.S. Application Data
(63) Continuation-in-part of application No. 15/601,963, filed on May 22, 2017.
Application No. 15/601,963 is a continuation of application No. 15/042,050, filed on Feb. 11, 2016, now Pat. No. 9,741,642.
Application No. 15/042,050 is a continuation-in-part of application No. 14/706,864, filed on May 7, 2015.
(60) Provisional application No. 62/429,314, filed on Dec. 2, 2016.
(60) Provisional application No. 62/126,262, filed on Feb. 27, 2015.
(60) Provisional application No. 61/990,040, filed on May 7, 2014.
(60) Provisional application No. 62/126,262, filed on Feb. 27, 2015.

(51) Int. Cl. H01L 23/495; H01L 23/31

(52) U.S. Cl. CPC H01L 23/49541; H01L 23/3114; H01L 23/49503

(57) ABSTRACT

A network computer system verifies users for a network service using verification input provided by existing users. The network computer system may determine a set of existing users of the network service based on information obtained from an information resource of the user's computing device. The network computer system may cause a mobile device of each existing user in the set to output content that includes an identifier of the user requesting verification. The network computer system may detect a response action generated in response to the provided content from at least one existing user of the set. The network computer system may determine an account value based on each detected response action.

### BACKGROUND

A network system can store and update account information of new and existing users. The account information of the new and existing users can include identifiers of an individual/user. Examples of identifiers can include a name, a photograph, and/or a mobile phone number.

### BRIEF DESCRIPTION OF THE DRAWINGS

FIG. 1 illustrates an example network computer system in communication with user device(s) to verify a user identity and/or the suitability of the user to perform a network service operation.

FIGS. 2A-2F illustrate an example set of user interfaces which can be generated to enable a user to have his or her identify verified by existing users of a network service.

FIG. 3A illustrates an example method for verifying users for a network service based on input of existing users of the network service.

FIG. 3B illustrates an example method for tracking a credibility of existing users for purpose of validating verification input provided by the individual existing users.

FIG. 4 illustrates a computer system upon which aspects described herein may be implemented.

FIG. 5 is a block diagram that illustrates a computer system upon which one or more embodiments described herein may be implemented.

Throughout the drawings, identical reference numbers designate similar, but not necessarily identical elements. The figures are not necessarily to scale, and the size of some parts may be exaggerated to more clearly illustrate the example shown. Moreover, the drawings provide examples and/or implementations consistent with the description. However, the description is not limited to the examples and/or implementations provided in the drawings.

### DETAILED DESCRIPTION

Examples provide for a network computer system that can verify an individual for an activity or role with a network service based on information that existing users of the network service can provide about that individual. In some examples, an identity of an individual can be verified by verification input of one or multiple other existing users. In variations, the suitability of an individual in a particular role (e.g., service provider, user, etc.) in connection with a network service can be gauged in part by input of other existing users of the network service. Still further, individuals can be recommended for a particular role based on an account value that weights input from existing users of the network service.

A network computer system verifies users for a network service using verification input provided by existing users. The network computer system may determine a set of existing users of the network service based on information obtained from an information resource of the user's computing device. The network computer system may cause a mobile device of each existing user in the set to output content that includes an identifier of the user requesting verification. The network computer system may detect a response action generated in response to the provided content from at least one existing user of the set. The network computer system may determine an account value based on each detected response action.

Some examples provide for a network computer system that operates to verify a user in connection with the user utilizing a network service, such as an on-demand service (e.g., a transportation service). By way of example, the network computer system can verify an identity of the user, or alternatively, a suitability of the user to use the network service in a specific capacity or role, (e.g., to fulfil an on-demand service request, to be included in an on-demand service request, to be able to request an on-demand service, etc.).

In some examples, a service requester (e.g., a rider) or a service provider (e.g., a driver) can request the network computer system to verify their identity by sending a verification request to the network computer system. The network computer system can identify one or more other individuals that are known or trusted, such as existing users, or users who have already subscribed to the network service. The network computer system can generate prompts on the mobile devices of the known or trusted users to cause those users to provide input relevant for the verification being sought (e.g., identity of the user).

In some examples, the network computer system identifies existing users of a network service based on an information resource (e.g., contact library, social network account, etc.) of the user for whom verification is being performed. For example, the network computer system may process, or trigger processing of contact records which are stored or accessible to a mobile device of the user being verified, in order to determine identifiers of existing users of the network service. Once existing users are identified, information resources of those users may be used to generate verification content, from which verification input can be prompted or otherwise solicited.

In some examples, the verification content can include an identifier of the requesting user, along with a prompt that solicits an input from the existing user (e.g., “Do you know this person?” “Do you trust this person to use the network service?”) A response action from each existing user may vary, based on implementation. For example, a response action may correspond to the existing user providing a binary type input (e.g., “Yes” to the prompt “Do you know this person?”), a qualitative or quantitative input (e.g., “A lot” or “3” to a prompt “How much do you trust this person?”). The response action may also infer a particular value. For example, if the user does not answer a prompt, the inference may be made that the existing user did not recommend the user seeking verification. Based on the response action of the other individuals that received the verification content, the network computer system can, for example, verify an identify of the user, or determine an account level of the user (e.g., based on recommendation or trustworthiness).

According to variations, various determinations may be made about a requesting user. For example, the response actions from the existing users can specify a value that indicates a reputation, trustworthiness, or other facet of the requesting user's character (e.g., politeness, driving ability, etc.).

Some examples are described in the context of on-demand transportation services, such as those in which a first user requests transport from a second user, or two users who do not know each other receive transport from a third user. While many examples are described in the context of on-demand transport, it will be appreciated that the network computing system can provide verification of users in various other contexts, such as in connection with delivery services (e.g., food items and products) or in connection with professional services.

One or more examples described herein provide that methods, techniques, and actions performed by a computing device are performed programmatically, or as a computer-implemented method. Programmatically, as used, means through the use of code or computer-executable instructions. These instructions can be stored in one or more memory resources of the computing device. A programmatically performed step may or may not be automatic.

Additionally, one or more examples described herein can be implemented using programmatic modules, engines, or components. A programmatic module, engine, or component can include a program, a sub-routine, a portion of a program, or a software component or a hardware component capable of performing one or more stated tasks or functions. As used herein, a module or component can exist on a hardware component independently of other modules or components. Alternatively, a module or component can be a shared element or process of other modules, programs, or machines.

Moreover, examples described herein can generally require the use of specialized computing devices, including processing and memory resources. For example, one or more examples described may be implemented, in whole or in part, on computing devices such as servers, desktop computers, cellular or smartphones, laptop computers, printers, digital picture frames, network equipment (e.g., routers), wearable computing devices, and tablet devices. Memory, processing, and network resources may all be used in connection with the establishment, use, or performance of any example described herein (including with the performance of any method or with the implementation of any system). For instance, a computing device coupled to a data storage device storing the computer program and configured to execute the program corresponds to a special-purpose computing device. Furthermore, any computing systems referred to in the specification may include a single processor or may be architectures employing multiple processor designs for increased computing capability.

Furthermore, one or more examples described herein may be implemented through the use of instructions that are executable by one or more processors. These instructions may be carried on a computer-readable medium. Machines shown or described with figures below provide examples of processing resources and computer-readable mediums on which instructions for implementing examples described can be carried and/or executed. In particular, the numerous machines shown with examples described include processor(s) and various forms of memory for holding data and instructions. Examples of computer-readable mediums include permanent memory storage devices, such as hard drives on personal computers or servers. Other examples of computer storage mediums include portable storage units, such as CD or DVD units, flash memory (such as carried on smartphones, multifunctional devices or tablets), and magnetic memory. Computers, terminals, network enabled devices (e.g., mobile devices, such as cell phones) are all examples of machines and devices that utilize processors, memory, and instructions stored on computer-readable mediums. Additionally, examples may be implemented in the form of computer-programs, or a computer usable carrier medium capable of carrying such a program.

Alternatively, one or more examples described herein may be implemented through the use of dedicated hardware logic circuits that are comprised of an interconnection of logic gates. Such circuits are typically designed using a hardware description language (HDL), such as Verilog and VHDL. These languages contain instructions that ultimately define the layout of the circuit. However, once the circuit is fabricated, there are no instructions. All the processing is performed by interconnected gates.

System Description

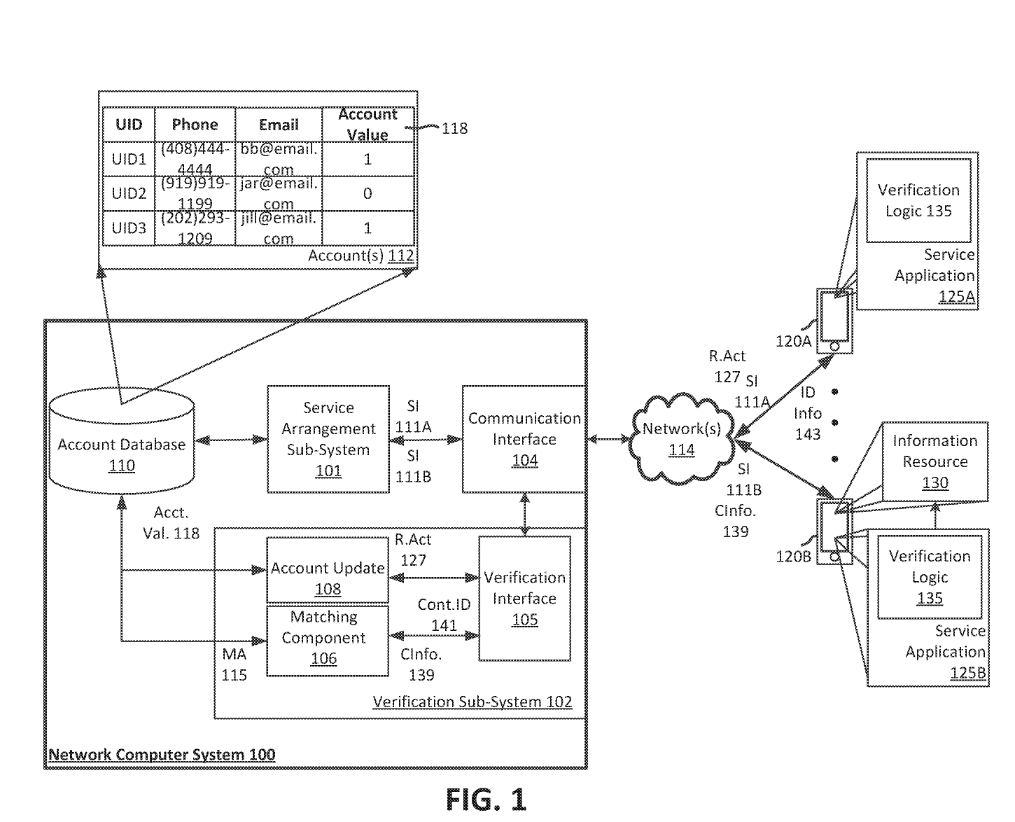

FIG. 1 illustrates an example network computer system in communication with user device(s) to verify individual users of a network service. As described, a network computer system 100 can implement or manage a network service for users that have roles as requesters and/or service providers. For example, the network computer system 100 can manage or implement an on-demand transport service for users who are requesters (e.g., riders) and service providers (e.g., drivers). Accordingly, in some examples, user device 120A is representative of user devices associated with service requesters (users requesting a service), and user device 120B is representative of user devices associated with service providers (users who can fulfill that requested service). In such examples, network computer system 100 can communicate with respective user devices 120A, 120B in order to match service requesters with service providers.

In some examples, network computer system 100 can communicate with respective user devices 120A, 120B in order to verify individual users. By way of example, the network computer system 100 can verify an identity of a service requester (e.g., a rider) or a service provider (e.g., a driver). As an addition or alternative, the network computer system 100 can verify the suitability or trustworthiness (e.g., a reputation or trustworthiness value or score) of the service provider or service requester for a particular role or credential. For example, the network computer system 100 can perform a verification process, as described by some examples, in order to provide a service provider with a temporary authorization, pending a final verification which may rely on original government-issued documentation and/or in-person interview. As another variation, the network computer system 100 can perform a verification process for a user, in order to verify the user for an account status in which the user can ride-share as a verified or trusted individual.

According to some examples, the network computer system 100 includes a service arrangement sub-system 101, a verification sub-system 102, a communication interface 104, and an account database 110. The communication interface 104 may communicate with numerous user device(s) 120A, 120B over network(s) 114 in order to implement and provide the network service. In some examples, the communication interface 104 communicates with the user devices 120A, 120B using service applications 125A, 125B that run on the respective devices. Each service application 125A, 125B can, for example, communicate with the network computer system 100, to enable secure communications and exchanges over the network 114, as well as to automate tasks and operations in connection with providing the network service. By way of example, service application 125A can enable the service requester to operate the user device 120A to request a service, and the service application 125B can enable a service provider of user device 120B to fulfill the service request.

In some examples, the service arrangement sub-system 101 implements an on-demand service, such as a transport service. The service arrangement sub-system 101 can, for example, utilize the communication interface 104 to receive service information 111A, 111B from the user devices 120A, 120B of the requesters and service providers. The service information 111A, 111B can include, for example, an account identifier of the respective user, the location of the corresponding user device, and/or a service status of each user. The service arrangement sub-system 101 can also receive, via the communication interface 104, a service request from the service requester operating the user device 120A.

The service application 125A can execute on the requester's user device 120A to output information provided by the network computer system 100. Such information may include, for example, the availability of one or more types of services, an expected wait time to receive a service, and/or the status of the user's service request. The service application 125A can also provide functionality for enabling the requester to make the service request. When communicating with the network computer system 100, the service application 125A can access a GPS or other location-aware resource to identify the location of the user device 120A. Thus, for example, the user device 120A may automatically integrate the location of the requester with a service request.

In similar fashion, the service application 125B can execute on the service provider's device 120B to provide the service provider with, for example, navigation information, or information relating to an assigned service request. The service provider can interact with the service application 125B to provide input, such as to change the service provider's status, to accept service requests, and to update a status of an open service request.

In some examples, the service arrangement sub-system 101 may process the service information 111A, 111B which is communicated by the various user devices in order to process service requests, assign service providers to service requests, monitor for completion of service requests, and/or transfer funds or proceeds from accounts of users based on services requested and/or provided. The service arrangement sub-system 101 may utilize a variety of factors or parameters in assigning service providers to service requests, including proximity and/or location information communicated from the respective user devices 120A, 120B.

According to some examples, the service requesters and/or service providers can operate their respective user devices 120A, 120B to request verification for a particular account status or service role. As described with other examples, the network computer system 100 can communicate with the respective user devices 120A, 120B via the corresponding service applications 125A, 125B, in order to (i) verify an identity of a user, (ii) verify information provided by a user (e.g., user nickname and home address), and/or (iii) verify suitability of the user for a given role or account status. In some examples, the service applications 125A, 125B may provide an interface to enable users to request verification. Additionally, the service applications 125A, 125B provide an interface to enable select responders to provide input that verifies (or not) users who request verification. Depending on implementation, the input can be binary (e.g., yes or no), trinary (e.g., yes, no, don't know), quantitative (e.g., ranking) and/or qualitative (e.g., comments).

The verification sub-system 102 can include, deploy or otherwise utilize distributed functionality in order to perform verification operations. In some examples, the verification sub-system 102 includes a verification interface 105, a matching component 106 and an account update logic 108. In some variations, the verification sub-system 102 may also include anonymization logic to preclude unauthorized use or access of personal identification information of users and non-users. The verification sub-system 102 can include, or otherwise control operation of a verification logic 135 that resides on individual user devices. In some examples, the verification logic 135 may be integrated, or otherwise provided with the service application(s) 125A, 125B of the user devices 120A, 120B. The verification logic 135 can be responsive to a verification event, such as a request by a service provider or requester to be verified. Accordingly, the verification event can correspond to a user input or action, which is detected by the verification logic 135 running on the individual user device 120A, 120B. In other examples, the verification event may correspond to a user request for verification, a user request to open a new account or to have an account status upgrade, a user request to receive a type of service, a user request to provide a type of service, and/or a user request to receive a credential for use with the network service. In some variations, the verification event can result from the user requesting verification from another verification source. For example, the verification sub-system 102 may perform verification operations in connection with a user seeking verification using a financial payment card or a national identification card (e.g., driver's license or government approved identification card).

In example of FIG. 1, the user device 120B is depicted as a source of the verification event (e.g., service provider requests verification), and the user device 120A is depicted as a source for verification event (e.g., existing user is requester of service). In variations, the verification event can be generated from verification logic 135 of requesters and/or service providers. Likewise, the verification input can be provided from existing users and service providers alike.

With respect to an example of FIG. 1, the verification logic 135 may respond to the verification event by accessing that device's information resource 130. The information resource 130 can include, for example, a locally stored set of contact records, and/or an interface (e.g., application, data pointers, etc.) to a network library of contact records. In some examples, the verification logic 135 aggregates select fields from individual contact records which are stored or accessible from the user device. The verification logic 135 may, for example, parse individual contact records for mobile phone numbers, or other types of identifiers (e.g., application identifier, email address, social network identifier, etc.) which are commonly in use with the account database 110. The resulting contact information 139 (e.g., mobile phone number of all contact records) can be communicated from the user device 120B to the verification sub-system 102 via the communication interface 104.

The verification interface 105 may receive and process the contact information 139 to determine a set of contact identifiers 141 which are provided with the information resource 130 of the user device 120B. According to some examples, the matching component 106 performs a search of the account database 110 using individual contact identifiers 141 (e.g., mobile phone numbers of contact records retrieved from the user device 120B), in order to determine matching user accounts which are associated with each of the individual contact identifiers 141. For example, mobile phone numbers retrieved from the contact information 139 of the user device 120B can be used as search criteria to identify matching accounts 115 in the account database 110 which are associated with those mobile phone numbers. In some examples, the matching component 106 can identify a set of device identifiers for the matching accounts 115. In such examples, the device identifiers correspond to computing devices which are used by existing users of the network service who match to contact information retrieved from the computing device of the user requesting verification.

In some examples, the contact information 139 can be anonymized using a hashing function, before being sent to the verification sub-system 102. The verification sub-system 102 may similarly hash select fields of the account database 110 in performing search or matching operations. The matching component 106 may thus implement a search of a hashed database, using a corresponding set of hashed contact information 139. As an addition or variation, the contact information 139 may also be encrypted for privacy and security when communicated between the network computer system 100 and the user device 120B.

The verification interface 105 may deploy and/or trigger verification logic 135 on the computing devices that are identified by the set of device identifiers 141 (represented by the user device 120A in FIG. 1). The verification interface 105 can also provide the user devices of the existing users, as identified by the set of device identifiers 141 (and collectively represented by user device 120A), with identification information 143 of the user seeking verification. In some examples, the network computer system 100 can use the service applications 125A, 125B residing on the devices identified by the device identifiers 141, in order to provide and/or trigger the verification logic 135, using the identification information 143 of the user seeking verification. The verification logic 135 may use the identification information 143 of the user seeking verification, in order to generate verification content that prompts the user in providing requested verification input. With reference to FIG. 1, the verification content that is generated on the user device 120A (operated by the existing user) can include the identification information 143 of the user seeking verification, as communicated from the verification sub-system 102.

As an addition or variation, the verification logic 135 can use the identification information 143 to search a local information resource of the existing user device 120A, in order to retrieve contact information of the user seeking verification. For example, the verification logic 135 can search the contact library stored on the user device 120A using identification information 143 corresponding to (i) a mobile phone number, (ii) last name, (iii) first name and last initial, and/or (iv) email address. If a match is found, the verification logic 135 may display, on the user device 120A, information from the matched content record in order to verify, for example, identification information provided by the user seeking verification. The verification logic 135 may also display content that combines information from the existing user's stored contact record with the user identification information 143, which may originate from input or account information of the user seeking verification. Thus, the verification logic 135 may be triggered to display, along with user identification information 143, a nickname, image, email address, moniker, or other identifier of the user seeking verification, based on the information the existing user has stored about the user seeking verification. For example, the verification logic 135 may display an image associated with a matching contact record for the user seeking verification, along with a text prompt to confirm the image is that of the user seeking verification. The verification logic 135 may also include content to identify the user seeking verification by legal name, nickname and last name, last name, email address or other identifier, using the local contact record and/or the user identification information 143. For example, the user seeking verification may identify her legal name as “Claire Doe,” and the user identification information may include the legal name, mobile device phone number, and email address. The verification logic 135 may search a contact library of the user device 120A (belonging to the existing user) for a matching mobile phone number or email address. As an addition or variation, the verification logic 135 may search by last name, first name or initials. If a match is found, the verification logic 135 may retrieve an image from the contact record, and display the image with a prompt that states (“Do you know Claire Doe?”). Alternatively, the verification logic 135 may display a nickname and request verification of other information provided by the user seeking verification (e.g., “Is ‘CD’ Claire Doe?”).

In other variations, the verification logic 135 may solicit input for other types of verification. For example, the verification logic 135 may solicit a recommendation (e.g., a score) for the user seeking verification as to their suitability for being a service provider (e.g., “Would you recommend Claire as a driver?”). Still further, as another example, the verification logic 135 may generate content to verify relevant demographic information provided by the user seeking verification (e.g., age and gender of the user seeking verification). As another example, the verification logic 135 may prompt the existing user for input that directly or indirectly gauges a particular characteristic of the user seeking verification (e.g., trustworthiness, caution, etc.). For example, the verification logic 135 may prompt for a response that can include a rating (e.g., 1/5) that is associated with a characteristic of the network service (e.g., politeness of a rider).

In some implementations, the network computer system 100 can obtain consent from the user seeking verification before the service application 125B accesses the information resource 130. The consent can be obtained through for example, a message communicated through the service application 125B.

The verification logic 135 can enable the existing user of user device 120A to provide a response to a generated prompt. In some examples, the requested input is binary (e.g., “Yes/No” or “True/False”) or trinary (“e.g., “Yes/No/Not Sure” or “True/False/Don't Know”). An input may also be interpreted as a no-response if no response is detected by the verification logic 135 within a set period of time. Still further, in other examples, the input may be a score, or even a qualitative expression. The verification logic 135 may detect a response action from the user. Examples of response actions may include a detected response input, no response detected, a text entry and/or a selection of a pre-determined response provided with content. In examples when no response is detected, the lack of response may be associated with a default response or value.

The service application 125A may communicate the response action 127 of the existing user to the network computer system 100. In some examples, account update logic 108 updates the account 112 of the user seeking verification with an account value 118. Depending on implementation, the account value 118 may correlate to a verification level for an identity of the user. In variations, the account value 118 may correlate to an authorization level for the user in connection with an activity or service level of the network service. Still further, in some variations, the account value 118 may correlate to a recommendation value for the user, based on input from existing users.

In some examples, the account value 118 may be of a defined set (e.g., verified, verification incomplete, not verified). In other examples, the account value 118 may correspond to a score, such as provided with a recommendation. In some examples, the account value can include a binary value (e.g., a “true” value to verify the identity of the user requesting verification, or a “false” value to deny verification). The account update logic 108 can implement, for example, rules which determine a verification level or status based on input from multiple existing users. For example, if one existing user responds with a negative response (e.g., not verified), the account update logic 108 can update the account value 118 to be unverified. The account update logic 108 may also apply rules to how non-responses are interpreted. For example, if no responses are detected from requested existing users, the no responses may be weighted more heavily, or alternatively, interpreted as unverified. Thus, for example, the account update logic 108 can incorporate rules that identify the number of existing users who were asked to verify a given user, the number of responses returned, the number of verified or positive responses, and the number of negative responses. In other examples, the account value 118 can correspond to a reputation value (e.g., a rating system) that can be averaged or aggregated based on input (or non-input) received from multiple existing users.

Depending on implementation, the account value 118 can enable a role, a permission (or set of permissions), and/or affect a service reputation. For example, a service provider may have his identity validated, at least temporarily pending validation from another more authoritative source (e.g., government validation). In such as example, when the service provider is validated temporarily, he or she may then use the network service as a service provider. Conversely, if the user is not verified, he or she may be precluded from operating as a service provider, or having another role. In a variation, the account value 118 may correspond to a trustworthiness credential value, based on recommendations or verifications provided by other existing users. When deemed trustworthy, the user may be given a permission to request a specific type of service (e.g., ride share with another rider), or perform a specific type of service. Still further, the account value 118 may be maintained as part of a reputation score, and other users may request services from or with individuals who have a specific threshold reputation score. For example, a user may request ride pool only with other users who have a reputation score above a given threshold.

In some examples, the account update logic 108 can maintain a credibility value with individual accounts 112 of existing users who provide verification input for other users. The credibility value can reflect the accuracy or veracity of verification input provided by the corresponding existing user. In one implementation, a user requesting verification may have multiple methods for verification available, such that a method of verification by existing users can be validated by another method (e.g., in-person submission of government submission). In one example, if the verification from existing users is validated by another verification method, the positive validation outcome may be used to increase (or make more credible) the credibility score of the existing users who provided verification input to verify the user.

According to some examples, if the verification performed through an alternative method identifies a user as using a fraudulent identification, while existing users verified the same user, the credibility score of the existing users may be negatively impacted. Moreover, in some examples, the credibility score of other users who may have verified existing users may also be negatively impacted. For example, the account update logic 108 may track verification input provided by existing users, such that the account update logic 108 can maintain a network identifying existing users providing verification input for other users. In the event a validation event occurs (e.g., verification by another method), where a user is deemed to have fraudulently identified themselves, the credibility score of existing users may be negatively affected, as well as the credibility score of other users who previously provided verification input for those existing users who provided the verification input.

While some examples provide that the credibility score can weight the verification input from a given user, in variations, a low credibility score can also indicate the corresponding user as being untrustworthy or unreliable. For such users, the credibility score may also impact the account value and/or impact the user's ability to have a role, credential or privilege with the network service.

Additionally, while an example describes the validation of verification to user identity, some examples provide for negatively impacting credibility scores of existing users when they provide verification input for a user that is subject to a subsequent contrary validation event. For example, one or more existing users may provide input that positively verifies the suitability of a given user for a role or credential with respect to the network service. However, a subsequent event (e.g., vehicle accident while providing transit services) may indicate the service provider was unfit for the role which verification was sought. In such an example, the account update logic 108 may negatively impact the credibility score of those users who provided the verification input for that service provider. More generally, if a given service provider performs poorly, and other users provided verification input that indicated the user would likely succeed in the role of service provider, then the credibility score of the existing users who provided the verification input may also be negatively impacted.

Network 114 can include one or more networks, such as a conventional type, wired or wireless network. Additionally, the network 114 can include an intranet, a local area network (LAN), a wide area network (WAN) (e.g., the Internet), and/or other interconnected data paths across which multiple devices can communicate. In some embodiments, network 114 can be a peer-to-peer network. Network 114 can also be coupled with or include portions of a telecommunications network for sending data using a variety of different communication protocols. In some embodiments, network 114 can include Bluetooth (or Bluetooth low energy) communication networks or a cellular communications network for sending and receiving data including via short messaging service (SMS), multimedia messaging service (MMS), hypertext transfer protocol (HTTP), direct data connection, WAP, email, etc. Although the examples of FIG. 1, each illustrate one network 114, network 114 can be more than one network. For example, as illustrated in FIG. 1, network computer system 100 and user device(s) 120A, 120B can communicate over network 114 using wired or wireless connections, or combinations thereof.

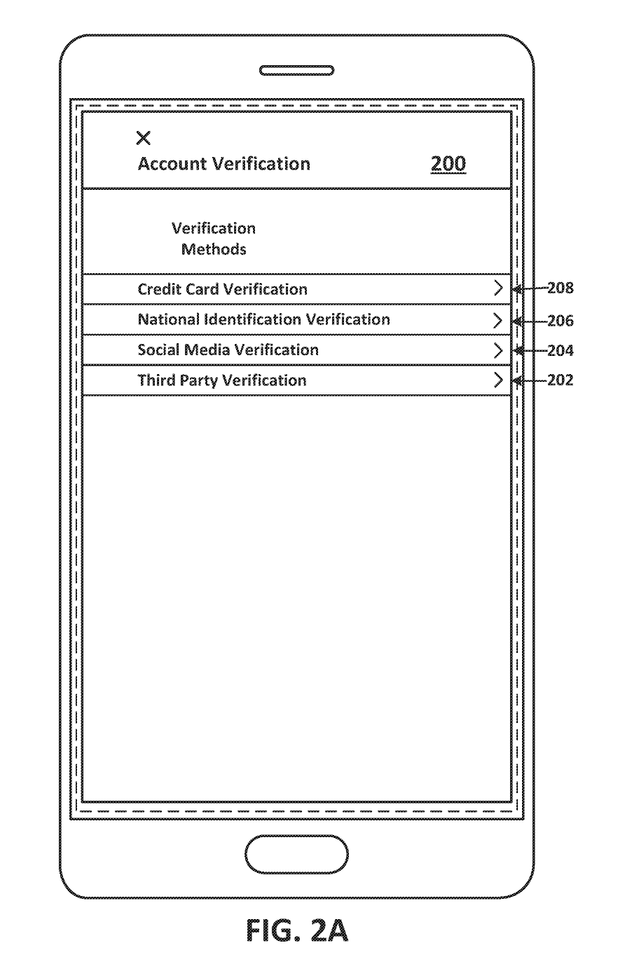

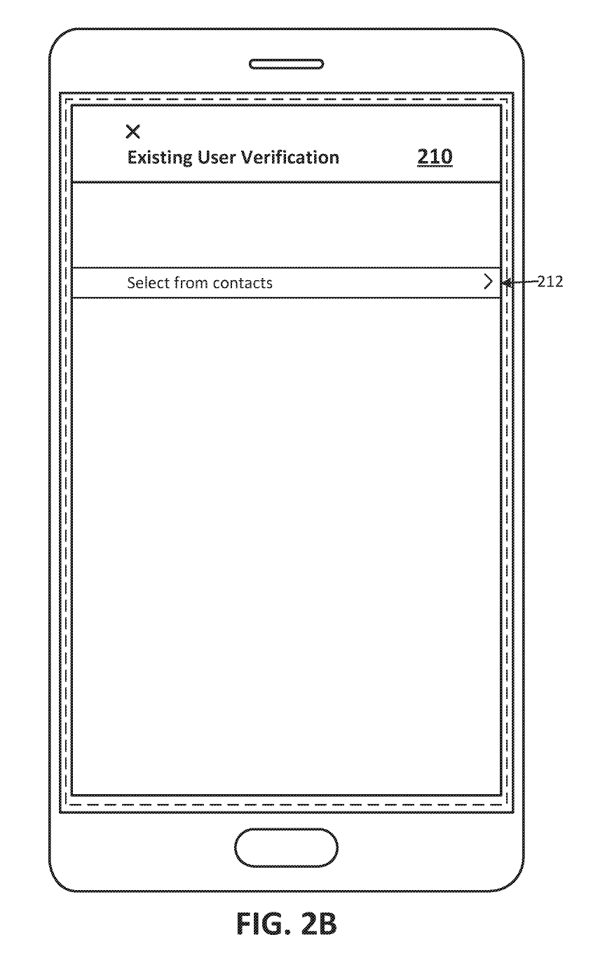

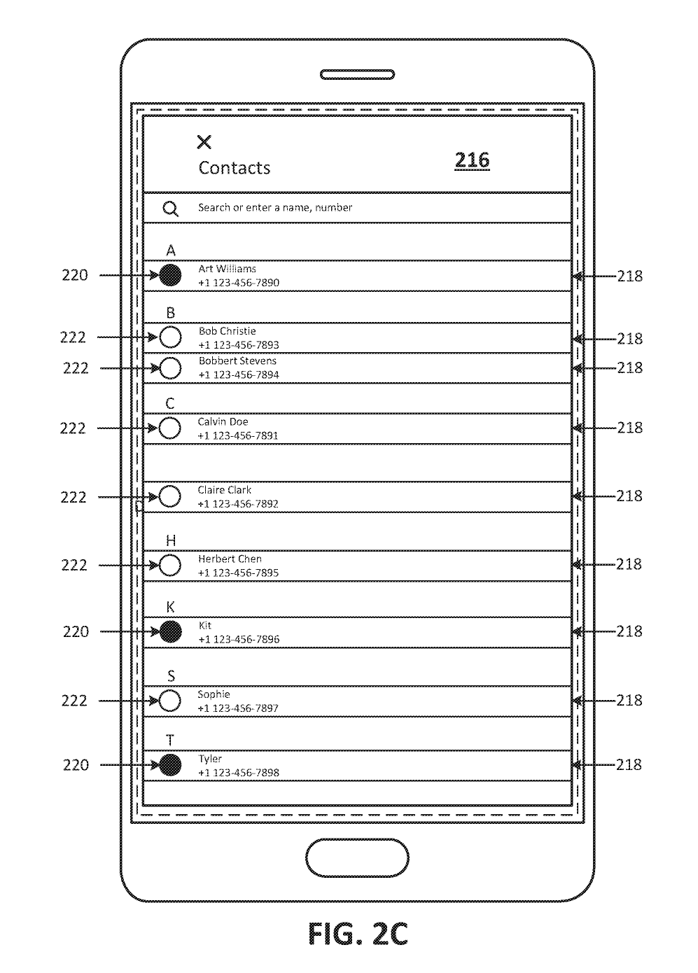

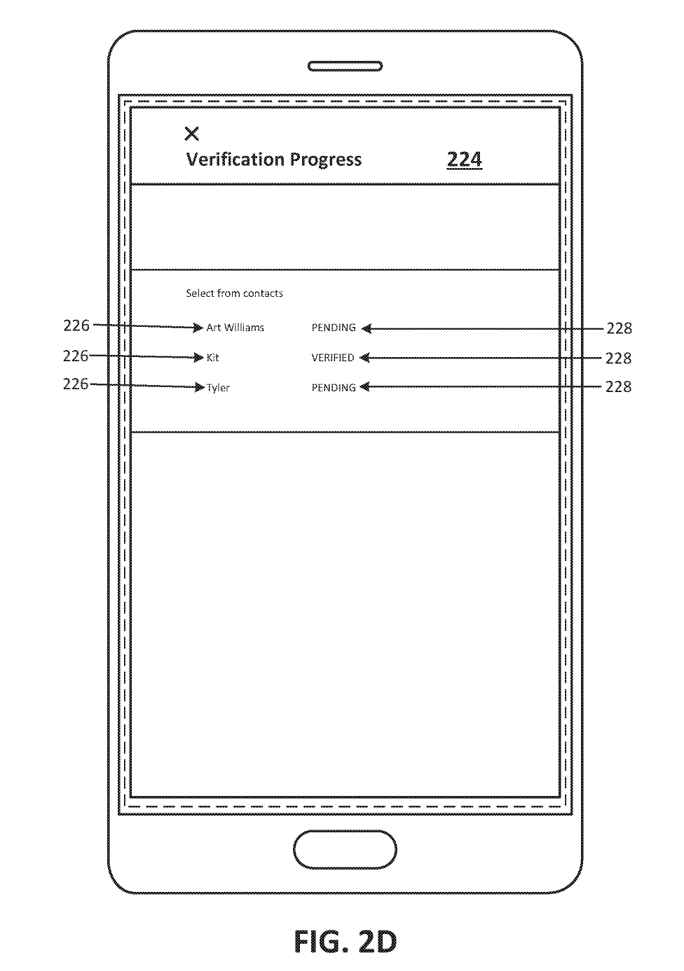

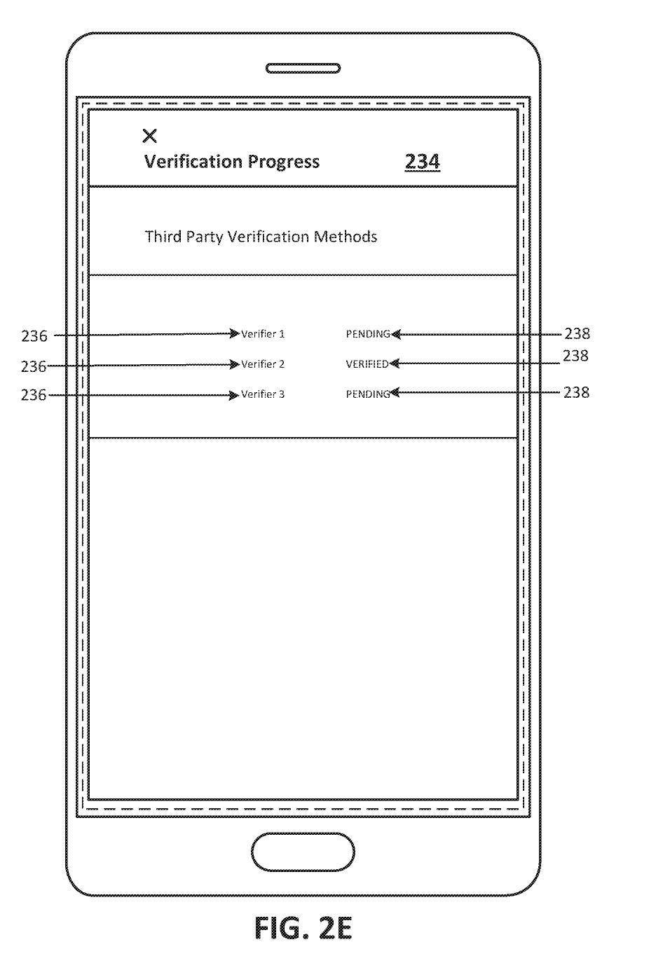

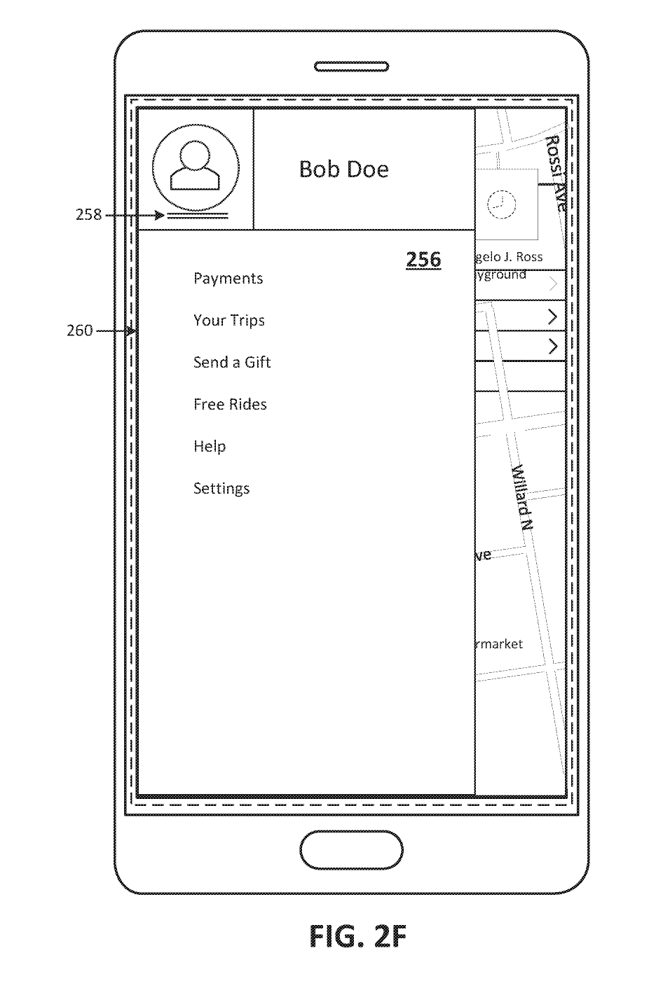

As described with examples of FIG. 2, the network computer system 100 can be used to provide application data to service applications 125A, 125B to generate various user interfaces (UIs). The various UIs can enable a user of device(s) 120A, 120B to (i) request verification of their own identity or information, and/or (ii) be requested to verify the identity of another user. Examples of UIs that can enable a user to trigger verification of their own identity or to verify the identity of another user are illustrated with examples of FIG, 2A through FIG. 2F.

FIGS. 2A-2F illustrate an example set of user interfaces which can be generated to enable a user to have his or her identify verified by existing users of a network service. The set of user interfaces, as described with examples of FIG. 2A through FIG. 2F, may be generated by, for example, service applications 125A, 125B operating on user devices 120A, 120B.

FIG. 2A illustrates an example user interface (“UI 200”) that enables a user to select a verification method for having his or her identity verified for use with a network service. In an example of FIG. 2A, the UI 200 enables the user to select a third-party verification method, with feature 202 being selectable to trigger verification from existing users of the network service. The UI 200 can also provide for the user to select other verification methods, such as verification by social media (feature 204), government verification (feature 206), and credit card verification (feature 208). The selection of feature 204 can trigger network computer system 100 to verify the user's identity using the social media accounts of the user. The selection of feature 206 can initiate a workflow where the user submits, or alternatively enables third-party access of a national identification card or document (e.g., driver's license or other government approved identification cards). The selection of feature 208 can trigger the network computer system (e.g., network computer system 100) to verify the user identity using a credit card account.

In some implementations, when a user selects one of the verification features, the service application 125A, 125B generates another UI that is based on the particular verification graphical feature that was selected by the user. Accordingly, in some examples, FIG. 2B and successive figures illustrate an example sequence of a user seeking verification through existing users of the network service.

FIG. 2B illustrates an example user interface (“UI 210”) that is generated on a computing device of the user requesting verification, in response to a user seeking verification from existing users of a network service. In an example shown, a user can select a feature 212 to permit the network computer system 100 to programmatically access the user's contact records (or other local information source). The user may select the feature 212 in connection with viewing or agreeing to the programmatic access of his or her contact records. For example, the network computer system 100 can provide a prompt on UI 210 to request a user to give consent in having his or her contact records accessed programmatically for verification purposes. The network computer system 100 can then access the contact library stored or available on the computing device of the user to determine a set of accounts for existing users of the network service (e.g., account(s) 112 stored in account database 110).

In some examples, the network computer system 100 accesses the user's contact library to identify contacts who may or may not verify the user's identity, and the identified contacts who are used to verify the user's identity are not disclosed to the user requesting verification. In variations such as shown with FIG. 2C, the user requesting verification may specify one or more contacts who can provide verification. In other variations, the user requesting verification may exclude certain contacts from making a verification, but the user may have no other input in selecting contacts from which the user may be verified.

FIG. 2C illustrates one variation in which a user interface (“UI 216”) is provided to the user in order to enable the user to select contact records for purpose of verifying the user. The UI 216 can include one or more entries 218, each of which correspond to a contact record stored in or associated with the corresponding user device 120A, 120B of the user identity being verified (e.g., device 120). Additionally, each entry 218 can include one or more identifiers of an individual (e.g., a name of the individual, a phone number of the individual, and/or an email address of the individual) based on the corresponding contact record. In some implementations, as illustrated in FIG. 2C, UI 216 can include a selection feature (e.g., selection feature 220 and selection feature 222) that is associated with each entry 218. The selection feature can enable a user to select or deselect a corresponding entry 218. The service application 125A, 125B of the corresponding user device 120A, 120B can send contact information 139 determined from those entries 218 that have been selected (e.g., using selection feature 220), to the network computer system 100. Alternatively, the contact information 139 can be determined programmatically, without input from the user seeking verification. For example, the service application 125A, 125B may execute to identify a mobile device number from a number of contact records on the user device 120A, 120B.

FIG. 2D and FIG. 2E illustrate alternative implementations for user interfaces for displaying a verification status to a user. FIG. 2D illustrates an example user interface (“UI 224”) that provides a representation of verification progress after a user has selected existing users to verify their identity. Multiple entries 226 may individually represent each contact selected by the user, and a status feature 228 may be provided with each entry 226 to indicate the status of the verification progress. In some examples, the status feature can indicate a particular step in the verification progress. In other examples, the status feature 228 can indicate if the verification progress is pending or complete.

FIG. 2E illustrates a variation of a user interface (“UI 234”) in which an identity of a contact being used for verification is anonymized. For example, the network computer system 100 may instruct the respective service application 125A, 125B to determine contact information 139 from contact records on the corresponding user device 120A, 120B, without informing the user as to which contacts were selected for the verification process. As illustrated in FIG. 2E, multiple entries 236 may be presented to the user, with each entry 236 representing a contact which is being used to verify the user, and each entry 236 being displayed with status information 238 indicating the status of receiving verification from the particular user. While a variation shown with an example of FIG. 2E displays entries for each contact without disclosing the contact's name, in other examples, the verification status may be based on an aggregation of the selected contacts, such that the verification status is reflective of the aggregation status of all of the contact records. Still further, while FIG. 2D and FIG. 2E illustrate example user interfaces 224, 234 in which the user receives progress information as to the verification status from specific contact entries, in variation, the status of verification requests to existing users may not be displayed.

FIG. 2F illustrates an example interface (“UI 256”) in which a visual cue is provided to indicate that the user's identity has been verified. In an example of FIG. 2F, UI 256 includes a menu panel 260 which includes a visual cue 258. The visual cue 258 can represent that the identity of the user and/or the suitability of the user to perform a network service operation has been verified, as described with various examples.

In some implementations, the service application 125A, 125B can generate one or more visual cues 258 which indicate a number of verification methods a user or user account has undergone. For example, a visual cue associated with a user or user account that has undergone two verification methods can be different from a visual cue associated with a user account that has undergone four verification methods. As an addition or variation, the service application 125A, 125B can generate or configure the visual cue 258 to reflect a type of verification method a user or user account has undergone. Thus, for example, in FIG. 2F, the visual cue 258 may vary based on the number of verification methods the user has undergone, as well as a type of each verification method the user has completed.

Methodology

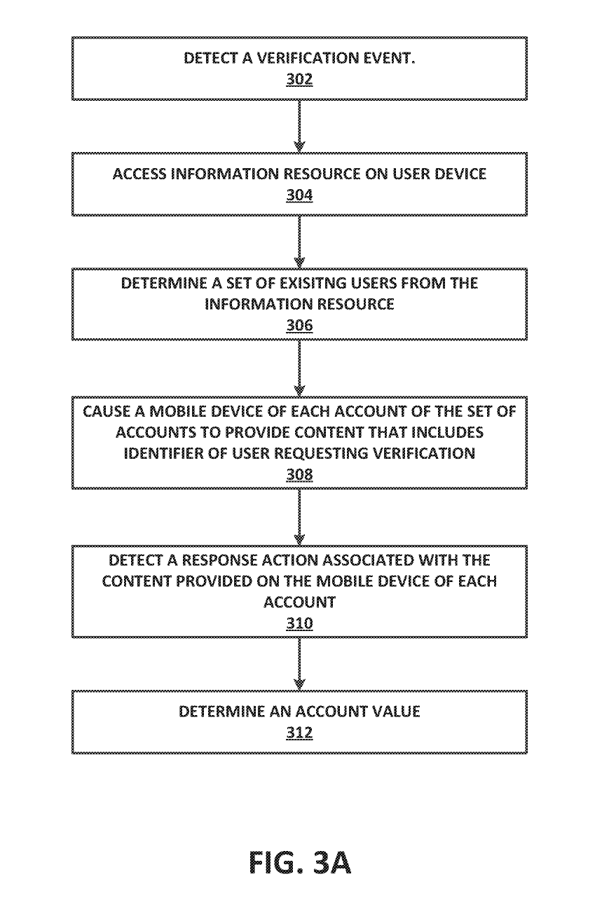

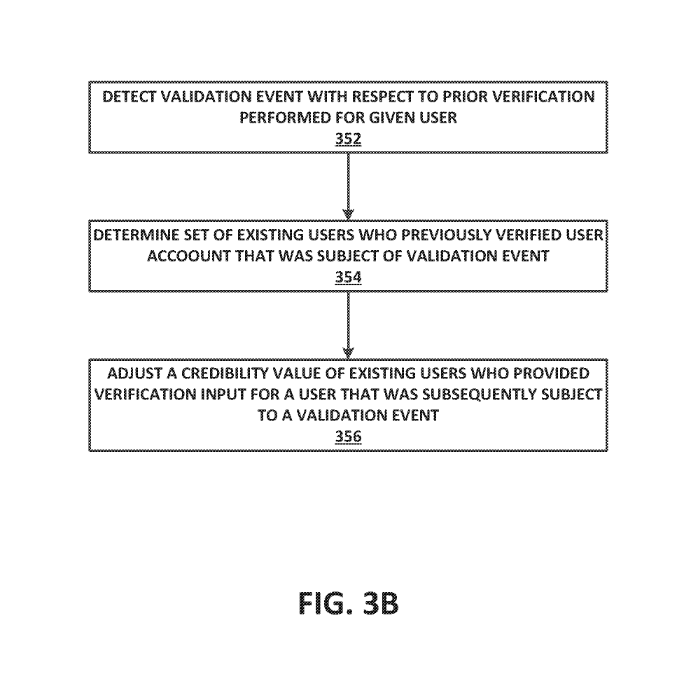

FIG. 3A illustrates an example method for verifying users for a network service based on input of existing users of the network service. FIG. 3B illustrates an example method for tracking a credibility of existing users for purpose of validating verification input provided by individual users. In describing an example of FIG. 3A and FIG. 3B, reference may be made to elements described with an example of FIG. 1 for purposes of illustrating a suitable component for performing a step or sub-step being described.

With reference to an example of FIG. 3A, network computer system 100 detects a verification event (302). In some examples, the verification event can include a user creating a new account, or requesting to have a specific role with a network service (e.g., trusted, service provider, etc.). In some examples, the verification event can be detected by a service application 125A, 125B, executing on a corresponding user device 120A, 120B, for a user that is to be verified. As described with other examples, the requested verification can be directed to identification of a given user, information provided by the given user, or the suitability of the given user for a role or credential.

In some examples, the verification event can correspond to a determination that the user is undergoing a rigorous time-consuming verification process (e.g., using a government certification to verify his or her identity). In such examples, network computer system 100 can utilize an example such as described with FIG. 3A, to make a temporary verification of the user. The temporary verification can be operative, pending the outcome of the more time-consuming verification method.

In some examples, an information resource 130 of the user may be accessed in response to detecting the verification event (304). The information resource may be locally stored dataset on a user device 120A, 120B, on which a respective service application 125A, 125B is executed. For example, the information resource may correspond to a user's contact library, as stored on a mobile device of the user.

A set of existing users of the network service are identified from the user's information resource 140 (306). For example, the information resource 130 may correspond with a contact records library that is resident on the user device 120A, 120B. Individual contact records can be accessed and parsed for contact information 139 (e.g., mobile phone numbers), using logic (e.g., verification logic 135) embedded or otherwise provided with the service application 125A, 125B. The contact information 139 can be determined for contacts selected by the user (e.g., such as shown by FIG. 2D), or programmatically (e.g., such as shown by FIG. 2E) using the service application 125A, 125B. In some examples, the contact information 139 may be hashed and/or encrypted and sent to the verification sub-system 102 of the network computer system 100, where the contact information can be used as search criteria against information stored with the account database 110. From the search, the verification sub-system 102 determines a set of existing users (or user accounts) who appear to have account information (e.g., mobile phone number) that match to individual contact records stored or provided with the information resource on the user device 120A, 120B of the user requesting verification.

The mobile device of each existing user in the set can be triggered to generate content that includes an identifier of the user requesting verification (308). For example, the verification sub-system 102 can identify a device of each existing user to trigger verification content. The verification sub-system 102 may send each identified device instructions to implement the verification logic 135, along with identification information 143 (e.g., name, mobile phone number, email address) of the user requesting verification. The instructions may cause the mobile device of the existing user to identify a contact record that matches the identification information 143 of the requesting user. The verification logic 135, which may be implemented by the service application 125A, 125B of the existing user, may generate content based at least in part on the locally stored contact record for the user requesting verification. For example, the generated content may display an image retrieved from the contact record of the user requesting verification, and the generated content may prompt the existing user to enter the name of the person depicted in the image. When multiple existing users are prompted for verification, some examples provide that the content generated on the respective user devices 120A, 120B to verify the same person may differ, based on information stored on the computing device of the individual existing users, with respect to the contact record for the user requesting verification.

The network computer system 100 may detect a response from individual existing users who are requested to provide verification input (310). The responses can include confirmations or denials (e.g., “true” or “false”) to prompts for verification of identity, or of information provided by users. The responses may alternatively include a quantitative input (e.g., score), such as when the verification is for whether the user is suitable for a particular role or credential with the network service.

In some implementations, the detected responses may also be non-responses. For example, in some examples, the service application 125A, 125B of existing users may be unable to match the identification information 143 of the user requesting verification with stored contact information. In other examples, the existing user may not be able to or willing to provide confirmation.

The network computer system may determine an account value based on each detected response action (312). In some examples, the verification sub-system 102 may aggregate or otherwise collect values representing the response action from existing users who are solicited for verification input. The verification sub-system 102 may implement logic to determine and/or update the account value of the account for the user being verified based on the determination made from the various responses. In some examples, the account value can include a binary value (e.g., a true value to verify the identity of the user or a false value to invalidate the identity of the identity of the user). In other examples, the account value can include a reputation value (e.g., a rating system).

With reference to an example of FIG. 3B, a validation event may be detected by the network computer system with respect to a prior verification performed for a given user (352). In the context of verification of a user identity, the validation event may correspond to, for example, results of verification performed by a highly trusted source (e.g., submission of government identification, in person meeting, etc.). The validation event may come out positive (e.g., the user was verified) or negative (e.g., the user was using a fraudulent identification). Determining on implementation, either type of event may correspond to a validation event.

In the context of verification of a user's suitability for a role or credential, the validation event may correspond to, for example, an event which is demonstrative that the user is suitable or unsuitable for a given role. For example, the user may have been verified as suitable for the role of provider, but then found to have been in a vehicle accident, or have attempted to defraud another user.

The validation event may pertain to an account that was previously verified by existing users of the network service, and the validation event may confirm or reject the results of the verification. The verification subsystem 102 may determine the set of existing users who previously verified the user account that was the subject of the validation event (354). According to some examples, the account update logic 108 may track verification provided by each existing user for the user requesting verification. For example, the account 112 of a verified user may identify accounts or individuals who verified that user.

The network computer system 100 may adjust a credibility parameter or value that is associated with existing users who provided verification input that was subsequently subject to a validation event, based on the outcome of the validation event (356). In some examples, each existing user may be associated with a credibility score. For example, the credibility score may provide a weight with respect to the influence of that user's input in verifying other users. The verification sub-system 102 may adjust the credibility score for the existing user based on the accuracy or veracity of the verification input provided by that user. The validation event may be characterized by outcome (e.g., user not verified by authoritative source) and/or kind (e.g., verification of identity, verification or suitability).

Based on the outcome and/or kind of validation input, the credibility score of the existing users who provided the verification inputs for the given user may be adjusted. For example, a credibility score of a user may be adjusted upward (more credible) if their verification input was positive (e.g., user identity was verified by independent and authoritative source), and the validation event confirmed their verification input. Likewise, the credibility score of the existing user may be adjusted upward if their verification input for a given user was negative, and the validation event confirmed their verification input (e.g., user was deemed to have a fraudulent credential).

In some examples, the verification sub-system 102 maintains a verification network which identifies, for each verified user, (i) the users who verified that person, and (ii) the other users whom that verified user verified. In some examples, certain types of validation events may affect multiple levels of the verification network. For example, if a user is deemed to have fraudulent credentials, the existing users who provided direct input (“direct verifiers”) to verify that user may have their credibility score negatively impacted. Additionally, the users who, from the verification network are determined to have verified the direct verifiers may also have their credibility score negatively impacted. The degree to which the credibility score is negatively impacted may be based on the degree of separation between the existing user who provided verification input and the user who was deemed to have fraudulent credentials.

Hardware Diagram

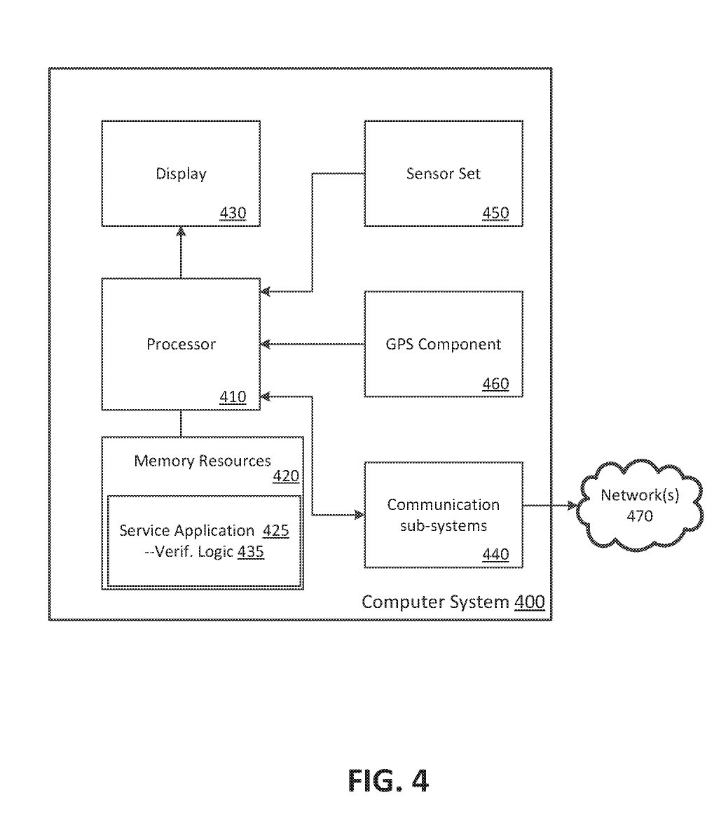

FIG. 4 is a block diagram that illustrates a computer system upon which examples described herein may be implemented. In one embodiment, a computing device 400 may correspond to a mobile computing device, such as a cellular device that is capable of telephony, messaging, and data services. The computing device 400 can correspond to a device operated by a requester or, in some examples, a device operated by the service provider that provides location-based services. Examples of such devices include smartphones, handsets, tablet devices, or in-vehicle computing devices that communicate with cellular carriers. The computing device 400 includes a processor 410, memory resources 420, a display device 430 (e.g., such as a touch-sensitive display device), one or more communication systems 440 (including wireless communication systems), a sensor set 450 (e.g., accelerometer and/or gyroscope, microphone, barometer, etc.), and one or more location detection mechanisms (e.g., GPS component) 460. In one example, at least one of the communication systems 440 sends and receives cellular data over data channels and voice channels. The communications systems 440 can include a cellular transceiver and one or more short-range wireless transceivers. The processor 410 can exchange data with a service arrangement system (not illustrated in FIG. 4) via the communications systems 440.

The processor 410 can provide a variety of content to the display 430 by executing instructions stored in the memory resources 420. The memory resources 420 can store instructions for the service application 425. The service application 425 may include verification logic 435, which can implement verification operations, such as described with examples of FIG. 1. The verification logic 435 can implement operations to (i) enable a verification request of a user by accessing an information resource (e.g., contact library as stored in the memory resources 420) to communicate contact identifiers (or an anonymized version of the contact identifier) to the network computer system 100; and/or (ii) generate verification content from which an existing user can provide input to verify another user requesting verification.

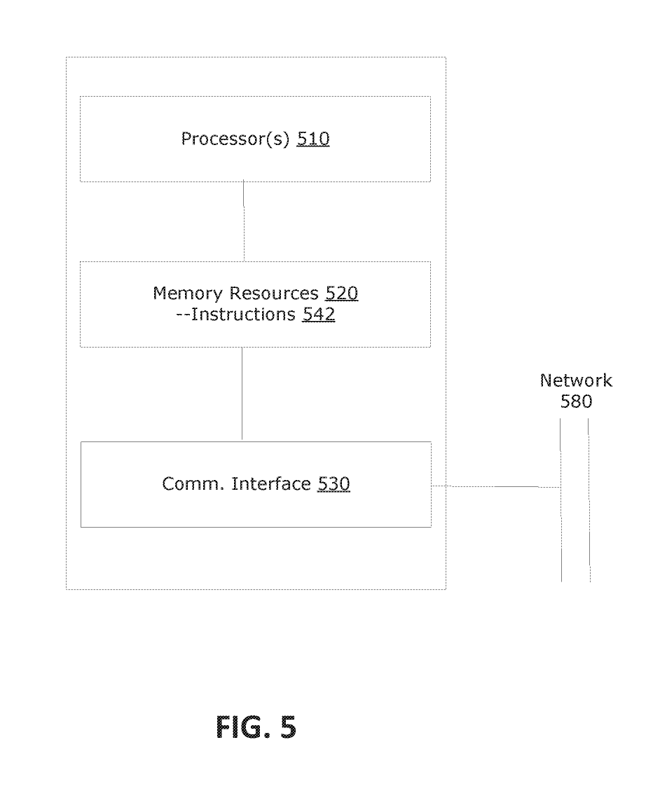

FIG. 5 is a block diagram that illustrates a computer system upon which one or more embodiments described herein may be implemented. For example, in the context of FIG. 1, the network computer system 100 may be implemented using a computer system or combination of computer systems, such as described by FIG. 5.

In one implementation, the computer system 500 includes one or more processors 510, memory resources 520, and a communication interface 530. The computer system 500 includes at least one processor 510 for processing information. The memory resources 420 may include a random-access memory (RAM) or other dynamic storage device, for storing information and instructions to be executed by the processor(s) 510. The memory resources 520 also may be used for storing temporary variables or other intermediate information during execution of instructions to be executed by the processor(s) 510. The computer system 500 may also include other forms of memory resources, such as static storage devices for storing static information and instructions for the processor 510. The memory resources 520 can store information and instructions, including instructions 542 implementing a verification sub-system 102, as described with an example of FIG. 1. Additionally, the processor(s) 510 can execute the instructions 542 to implement a method such as described with an example of FIG. 3A or FIG. 3B.

The communication interface 530 can enable the computer system 500 to communicate with one or more networks 580 (e.g., cellular network) through use of the network link (wireless or wireline). Using the network link, the computer system 500 can communicate with one or more other computing devices and/or one or more other servers or data centers. In some variations, the computer system 500 can receive service requests from requester devices via the network link 580. Additionally, the computer system 500 can receive information from provider devices, from which forecasts of provisioning levels, location bias and other aspects described herein may be determined.

Examples described herein are related to the use of the computer system 600 for implementing the techniques described herein. According to one embodiment, those techniques are performed by the computer system 500 in response to the processor 510 executing one or more sequences of one or more instructions contained in the memory resource 520. Such instructions may be read into a main memory from another machine-readable medium, such as a storage device. Execution of the sequences of instructions contained in the main memory 520 causes the processor 510 to perform the process steps described herein. In alternative implementations, hard-wired circuitry may be used in place of or in combination with software instructions to implement examples described herein. Thus, the examples described are not limited to any specific combination of hardware circuitry and software.

Examples described herein to extend to individual elements and concepts described herein, independently of other concepts, ideas or system, as well as for examples to include combinations of elements recited anywhere in this application. Although examples are described in detail herein with reference to the accompanying drawings, it is to be understood that the concepts are not limited to those precise examples. Accordingly, it is intended that the scope of the concepts be defined by the following claims and their equivalents. Furthermore, it is contemplated that a feature described either individually or as part of an example can be combined with other individually described features, or parts of other examples, even if the other features and examples make no mentioned of the feature. Thus, the absence of describing combinations should not preclude having rights to such combinations.

What is claimed is:

1. A method for operating a network computer system, the method being implemented by one or more processors and comprising:
detecting a verification event for a user, in connection with the user utilizing a network service;
in response to detecting the verification event, identifying an information resource of the user;
determining a set of existing users of the network service based on information obtained from the information resource;
causing a mobile device of each existing user in the set to output content that includes an identifier of the user;
detecting a response action generated in response to the outputted content from at least one existing user of the set of existing users;
generating an account value for the user, based on each detected response action.

2. The method of claim 1, wherein the information resource of the user includes at least one of (i) information stored on a mobile device of the user, or (ii) an account associated with the user accessible from the mobile device of the user.

3. The method of claim 2, wherein determining the set of existing users includes determining at least a first existing user based on a name, device identifier, or messaging identifier of a contact record that is either stored on the mobile device of the user, or provided with the account of the user.

4. The method of claim 3, wherein determining at least the first existing user includes matching the name, device identifier, or messaging identifier of the contact record with corresponding information associated with an account of the first existing user with the network service.

5. The method of claim 1, wherein causing a mobile device of each existing user in the set to output content includes causing the mobile device of each existing user to output content that includes a corresponding name or image of the user, along with a prompt for input from the existing user.

6. The method of claim 5, wherein causing the mobile device of each existing user in the set to output content includes matching a name, a device identifier or a messaging identifier of the user with information provided with a contact record that is stored or accessible on the mobile device of that existing user.

7. The method of claim 6, wherein the content outputted on the mobile device of each existing user is specific to information provided with the contact record that is stored or accessible on that mobile device.

8. The method of claim 7, wherein the content outputted on the mobile device of each existing user includes a nickname or image that is provided with the matching contact record that is stored or accessible on that mobile device.

9. The method of claim 6, wherein the prompt enables the existing user to specify a binary value.

10. The method of claim 1, wherein detecting the verification event is performed in connection with an action of the user to use the network service in capacity of a role.

11. The method of claim 10, wherein the role is of a service provider.

12. The method of claim 1, wherein the account value correlates to a verification level for an identity of the user.

13. The method of claim 1, wherein the account value correlates to an authorization level for the user in connection with an activity or service level of the network service.

14. The method of claim 1, wherein the account value correlates to one or more of a recommendation value, credibility value, or reputation score for the user.

15. A network computer system for operating a network service, comprising:
one or more processors; and
one or more memory resources storing instructions that, when executed by the one or more processors, cause the one or more processors to:
detect a verification event for a user, in connection with the user utilizing a network service;
in response to detecting the verification event, identify an information resource of the user;
determine a set of existing users of the network service based on information obtained from the information resource;
cause a mobile device of each existing user in the set to output content that includes an identifier of the user;
detect a response action generated in response to the outputted content from at least one existing user of the set of existing users;
determine an account value for the user, based on each detected response action.

16. The network computer system claim 15, wherein the information resource of the user includes at least one of (i) information stored on a mobile device of the user, or (ii) an account accessible from the mobile device of the user.

17. The network computer system of claim 16, wherein the one or more processors determine the set of existing users by determining at least a first existing user based on a name, device identifier, or messaging identifier of a contact record that is either stored on the mobile device of the user, or provided with the account of the user.

18. The network computer system of claim 15, wherein the account value correlates to at least one of verification level for an identity of the user, an authorization level for the user in connection with an activity or service level of the network service, or a recommendation value for the user.

19. The network computer system of claim 15, wherein the one or more processors instruct the mobile device of each existing user in the set to output content using contact information stored with a contact record for the user.

20. A non-transitory computer readable medium storing instructions that, when executed by one or more processors of a network computer system, cause the one or more processors to:
detect a verification event for a user, in connection with the user utilizing a network service;
in response to detecting the verification event, identify an information resource of the user;
determine a set of existing users of the network service based on information obtained from the information resource;
cause a mobile device of each existing user in the set to output content that includes an identifier of the user;
detect a response action generated in response to the outputted content from at least one existing user of the set of existing users; and
determine an account value for the user, based on each detected response action.
